(19) United States
(12) Patent Application Publication
(10) Pub. No.: US 2025/0140635 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Yu KE, Taichung City (TW); Liang-Pin CHEN, Taichung City (TW)

(21) Appl. No.: 18/618,241

(22) Filed: Mar. 27, 2024

(30) Foreign Application Priority Data
Oct. 26, 2023 (TW) 112141124

(51) Int. Cl. H01L 23/367; H01L 23/373; H01L 23/498

(52) U.S. Cl. CPC H01L 23/3675; H01L 23/3736; H01L 23/49816

(57) ABSTRACT

An electronic package and a manufacturing method thereof are provided, in which an electronic element is disposed on a carrier structure, and the electronic element is encapsulated by a heat dissipation covering layer, and the heat dissipation covering layer is in contact with a metal layer formed on a side surface of the carrier structure, so that heat around the electronic element can be dissipated quickly to effectively avoid a problem of failure of the electronic element due to overheating during operation.

### CROSS-REFERENCE TO RELATED APPLICATIONS

The present application is based upon and claims the right of priority to Taiwan Patent Application No. 112141124, having a filing date of Oct. 26, 2023, the disclosure of which is hereby incorporated by reference herein in its entirety for all purposes.

### BACKGROUND

### 1. Technical Field

The present disclosure relates to a semiconductor packaging technology, and more particularly, to an electronic package that can improve heat dissipation performance and a manufacturing method thereof.

### 2. Description of Related Art

As the requirements for functionality and processing speed of electronic products increase, semiconductor chips served as the core components of electronic products need to have higher density electronic elements and electronic circuits. Therefore, the semiconductor chips will generate a greater amount of heat energy during operation, which is especially significant for package stack structures with multiple chips.

As shown in FIG. 1, in a conventional semiconductor package 1, a semiconductor chip 11 is bonded onto a package substrate 10 in a flip-chip manner, and a plurality of conductive pillars 13 are formed on the package substrate 10, and then an encapsulant 15 is formed on the package substrate 10 to cover the semiconductor chip 11 and the conductive pillars 13, and the conductive pillars 13 are exposed from the encapsulant 15 for external connection to another electronic module 1a.

However, in the conventional semiconductor package 1, since a thermal conductivity of the encapsulant 15 is poor and the semiconductor chip 11 is embedded in the encapsulant 15, heat is easily accumulated around the semiconductor chip 11, such that the semiconductor chip 11 is prone to failure due to overheating during operation, causing the terminal electronic product to be scrapped.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; an electronic element bonded on and electrically connected to the carrier structure; a heat dissipation covering layer formed on the carrier structure and covering the electronic element; and a metal layer formed on a side surface of the carrier structure and in contact with the heat dissipation covering layer.

The present disclosure also provides a method of manufacturing an electronic package, the method comprises: providing a carrier structure disposed with an electronic element, wherein the electronic element is electrically connected to the carrier structure; forming a heat dissipation covering layer on the carrier structure, wherein the electronic element is covered by the heat dissipation covering layer; and forming a metal layer on a side surface of the carrier structure, wherein the metal layer is in contact with the heat dissipation covering layer.

In the aforementioned electronic package and method, a material forming the heat dissipation covering layer is a metal material.

In the aforementioned electronic package and method, a material forming the heat dissipation covering layer is a thermally conductive insulating material.

In the aforementioned electronic package and method, the present disclosure further comprises forming at least one conductive pillar on the carrier structure, wherein the conductive pillar is electrically connected to the carrier structure. For example, the heat dissipation covering layer is in contact with the conductive pillar. Alternatively, the heat dissipation covering layer has an opening, and the conductive pillar passes through the opening without touching the opening. Furthermore, the present disclosure comprises forming a circuit structure on the heat dissipation covering layer, wherein the circuit structure is electrically connected to the conductive pillar.

In the aforementioned electronic package and method, the present disclosure further comprises forming a packaging layer on the carrier structure to cover the electronic element and the heat dissipation covering layer. For example, the present disclosure further comprises forming at least one conductive pillar on the carrier structure, wherein the conductive pillar is electrically connected to the carrier structure and embedded in the packaging layer. Further, the present disclosure also comprises forming a circuit structure on the packaging layer, wherein the circuit structure is electrically connected to the conductive pillar.

As can be understood from the above, in the electronic package and the manufacturing method thereof of the present disclosure, the heat dissipation covering layer with excellent thermal conductivity is in contact with the metal layer on the side surface of the carrier structure, so that heat around the electronic element is quickly dissipated. Therefore, compared with the prior art, the electronic element is covered by the heat dissipation covering layer in the present disclosure, which can effectively avoid the problem of failure of the electronic element due to overheating during operation, thereby avoiding the problem of scrapping terminal electronic products.

### BRIEF DESCRIPTION OF THE DRAWINGS

FIG. 1 is a schematic cross-sectional view of a conventional semiconductor package.

FIG. 2A to FIG. 2G are schematic cross-sectional views illustrating a method of manufacturing an electronic package according to a first embodiment of the present disclosure.

FIG. 2H is a schematic partial top view of FIG. 2G.

FIG. 3A is a schematic cross-sectional view of an electronic package according to a second embodiment of the present disclosure.

FIG. 3B is a schematic partial top view of FIG. 3A.

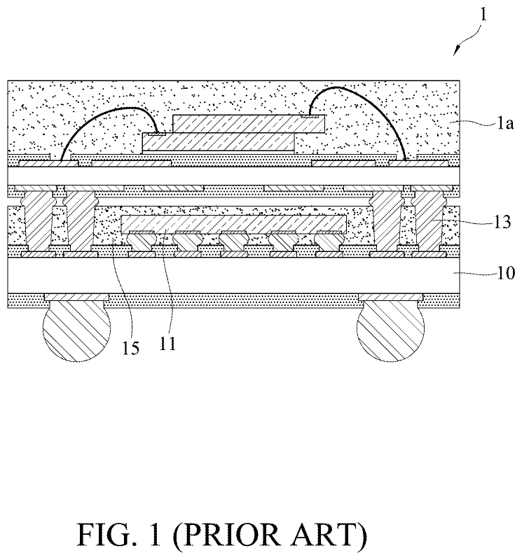

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “below,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

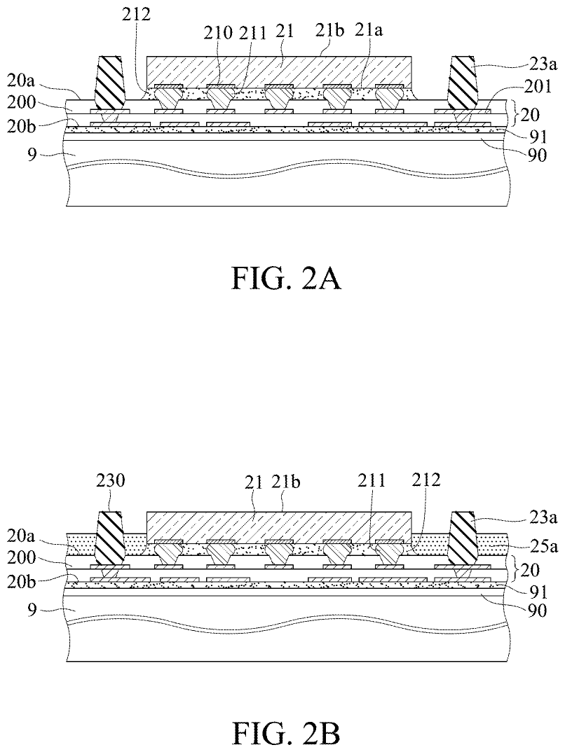

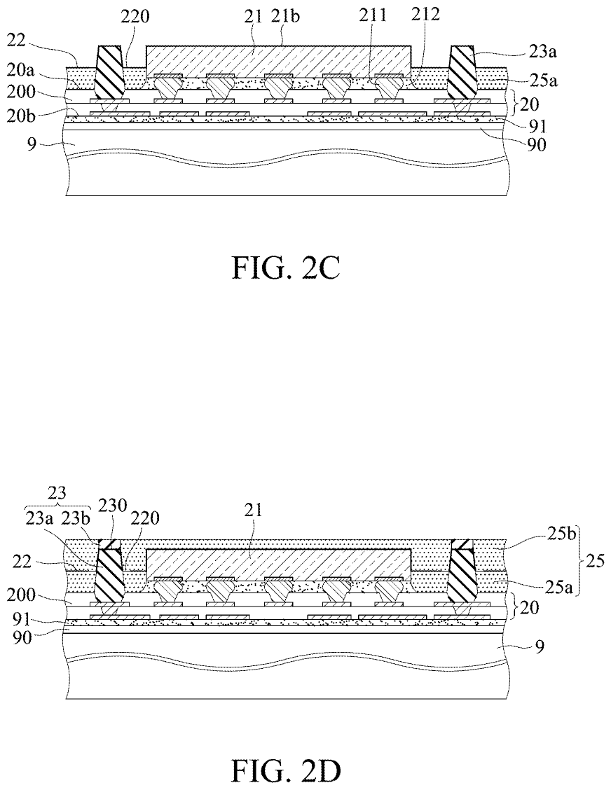

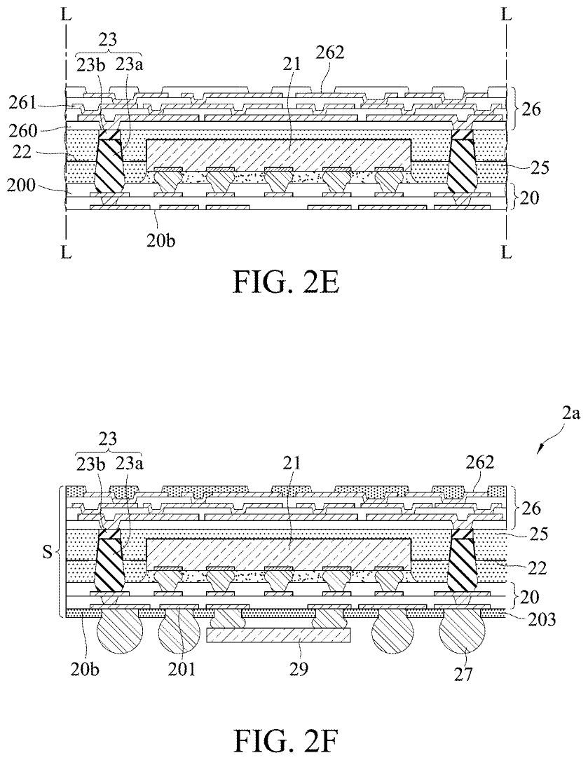

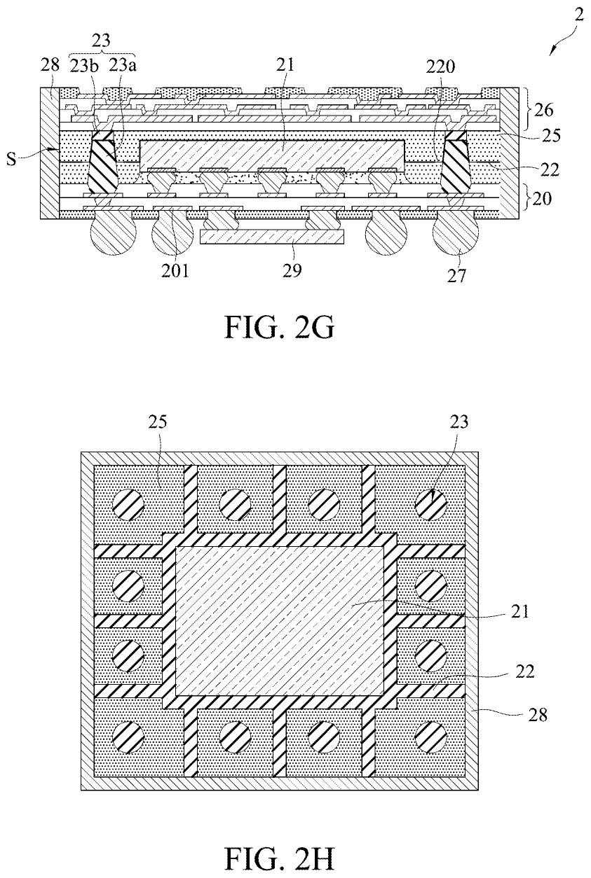

FIG. 2A to FIG. 2G are schematic cross-sectional views illustrating a method of manufacturing an electronic package 2 according to a first embodiment of the present disclosure.

As shown in FIG. 2A, a carrier structure 20 is disposed on a carrier board 9, and a plurality of first conductive pillars 23a are formed on the carrier structure 20, and at least one electronic element 21 is disposed on the carrier structure 20.

The carrier board 9 is, for example, a board body made of semiconductor material (such as silicon or glass), on which a release layer 90 and an adhesive layer 91 can be formed sequentially as required.

The carrier structure 20 has a first side 20a and a second side 20b opposing the first side 20a, and the first side 20a is provided with the plurality of first conductive pillars 23a and the electronic element 21, and the second side 20b is bonded to the adhesive layer 91. For example, the carrier structure 20 is a package substrate having a core layer and a circuit structure, a package substrate with a coreless circuit structure, a through-silicon interposer (TSI) having through-silicon vias (TSVs), or other board types.

In an embodiment, the carrier structure 20 is a coreless package substrate formed by a redistribution layer (RDL) manufacturing method, and the carrier structure 20 comprises at least one insulating layer 200 formed on the adhesive layer 91 and a wiring layer 201 bonded to the insulating layer 200. For example, the wiring layer 201 is made of copper, and the insulating layer 200 is made of dielectric materials such as polybenzoxazole (PBO), polyimide (PI), prepreg (PP), etc.

The first conductive pillars 23a are formed on the wiring layer 201 of the first side 20a in a manner of electroplating to electrically connect the wiring layer 201.

In an embodiment, a material forming the first conductive pillars 23a is a metal material such as copper or a solder material.

The electronic element 21 is an active element, a passive element, or a combination of the active element and the passive element, wherein the active element may be a semiconductor chip, and the passive element may be a resistor, a capacitor, or an inductor.

In an embodiment, the electronic element 21 is a semiconductor chip and has an active surface 21a and an inactive surface 21b opposing the active surface 21a, and electrode pads 210 of the active surface 21a are disposed on the wiring layer 201 by a plurality of conductive bumps 211 such as copper pillars, solder balls, etc. in a flip-chip manner and are electrically connected to the wiring layer 201 of the first side 20a, and the conductive bumps 211 are covered by an underfill 212; or, the electronic element 21 is disposed on the carrier structure 20 with the inactive surface 21b thereof and can be electrically connected to the wiring layer 201 by a plurality of bonding wires (not shown) in a wire bonding manner. However, the manner in which the electronic element 21 is electrically connected to the wiring layer 201 is not limited to the above.

As shown in FIG. 2B, a first encapsulating layer 25a is formed on the first side 20a of the carrier structure 20, so that the first encapsulating layer 25a covers the electronic element 21, the underfill 212 and the first conductive pillars 23a, wherein the first encapsulating layer 25a is bonded to the insulating layer 200. Then, an upper surface of the first encapsulating layer 25a is lower than end surfaces 230 of the first conductive pillars 23a and the inactive surface 21b of the electronic element 21 by the removal process, such that the end surfaces 230 of the first conductive pillars 23a and the inactive surface 21b of the electronic element 21 are exposed from the first encapsulating layer 25a.

In an embodiment, the first encapsulating layer 25a is made of an insulating material, such as polyimide (PI), dry film, encapsulant of epoxy resin, or molding compound, and the first encapsulating layer 25a can be formed on the insulating layer 200 by lamination or molding.

As shown in FIG. 2C, a heat dissipation covering layer 22 is formed on the upper surface of the first encapsulating layer 25a and on portions of the first conductive pillars 23a and the electronic element 21 that are exposed from the first encapsulating layer 25a.

In an embodiment, the heat dissipation covering layer 22 is made of metal material, such as copper material. For example, the heat dissipation covering layer 22 is formed by electroplating or other methods so that the thickness of the heat dissipation covering layer 22 is extremely thin.

Furthermore, the heat dissipation covering layer 22 has at least one opening 220, so that the heat dissipation covering layer 22 is not connected between two of the first conductive pillars 23a, as shown in FIG. 2H.

As shown in FIG. 2D, a second conductive pillar 23b is formed on each of the first conductive pillars 23a, and then a second encapsulating layer 25b is formed on the first encapsulating layer 25a, so that the second encapsulating layer 25b covers the heat dissipation covering layer 22 and the plurality of second conductive pillars 23b.

In an embodiment, the second conductive pillar 23b is formed on the heat dissipation covering layer 22 of the end surface 230 of each of the first conductive pillars 23a in an electroplating manner to electrically connect the first conductive pillar 23a.

Furthermore, the second encapsulating layer 25b is made of an insulating material, such as polyimide (PI), dry film, encapsulant of epoxy resin, or molding compound, and the second encapsulating layer 25b can be formed on the first encapsulating layer 25a by lamination or molding. It should be understood that the material forming the first encapsulating layer 25a and the material forming the second encapsulating layer 25b may be the same or different.

Also, as required, an outer surface of the second encapsulating layer 25b can be flush with top ends of the plurality of second conductive pillars 23b by a leveling process, such as grinding, so that the plurality of second conductive pillars 23b are exposed from the second encapsulating layer 25b.

In addition, the second encapsulating layer 25b is in contact with and bonded to the first encapsulating layer 25a via the opening 220, so that the first encapsulating layer 25a and the second encapsulating layer 25b are served as a packaging layer 25, meanwhile, the connected first conductive pillar 23a and second conductive pillar 23b together form a conductive pillar 23, wherein a portion of the heat dissipation covering layer 22 is sandwiched between the first conductive pillar 23a and the second conductive pillar 23b.

As shown in FIG. 2E, a circuit structure 26 is formed on the second encapsulating layer 25b, and the circuit structure 26 is electrically connected to the plurality of conductive pillars 23. Then, the carrier board 9 and the release layer 90 and the adhesive layer 91 thereon are removed to expose the second side 20b of the carrier structure 20.

In an embodiment, the circuit structure 26 comprises a plurality of dielectric layers 260 and a plurality of circuit layers 261 with fan-out type redistribution layer (RDL) formed on the dielectric layers 260, and the outermost dielectric layer 260 can be used as a solder-resist layer, so that the outermost circuit layer 261 is partially exposed from the solder-resist layer and served as electrical contact pads 262 for external connection to another electronic module or other electronic components (not shown). For example, the circuit layer 261 is made of copper, and the dielectric layer 260 is made of dielectric material such as polybenzoxazole (PBO), polyimide (PI), prepreg (PP), etc.

As shown in FIG. 2F, a plurality of conductive elements 27 such as solder balls are formed on the wiring layer 201 of the second side 20b of the carrier structure 20, such that the plurality of conductive elements 27 are electrically connected to the conductive pillars 23 and/or the electronic element 21. Then, a singulation process is performed along a cutting path L shown in FIG. 2E to obtain a package module 2a, and side surfaces of the carrier structure 20, the first encapsulating layer 25a, the second encapsulating layer 25b and the circuit structure 26 are together configured as a side surface S of the package module 2a, so that the heat dissipation covering layer 22 is exposed from the side surface S of the package module 2a.

In an embodiment, an insulating protective layer 203 such as a solder-resist layer can be formed on the insulating layer 200 of the second side 20b, and a plurality of openings are formed on the insulating protective layer 203, such that the wiring layer 201 is exposed from the openings for bonding the conductive elements 27.

Furthermore, at least one auxiliary functional element 29, such as a passive element, can be connected onto the wiring layer 201 of the second side 20b of the carrier structure 20.

As shown in FIG. 2G, a metal layer 28 connected to the heat dissipation covering layer 22 is formed on the side surface S of the package module 2a.

Therefore, in the manufacturing method of the present disclosure, the heat dissipation covering layer 22 with excellent thermal conductivity is embedded in the packaging layer 25 and in contact with the metal layer 28 so as to quickly dissipate heat around the electronic element 21. Therefore, compared with the prior art, the electronic element 21 is covered by the heat dissipation covering layer 22 in the present disclosure, which can effectively avoid the problem of failure of the electronic element 21 due to overheating during operation, thereby avoiding the problem of scrapping terminal electronic products.

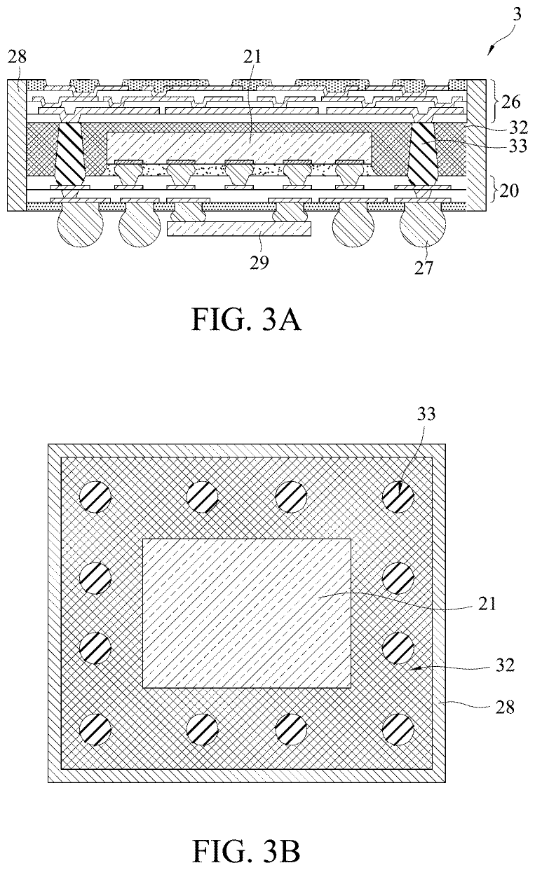

Please refer to an electronic package 3 shown in FIG. 3A and FIG. 3B (a second embodiment of the present disclosure), in which the configuration of the first encapsulating layer 25a and the second encapsulating layer 25b can be omitted, so that in the process shown in FIG. 2B, the thermally conductive insulating material is formed on the insulating layer 200 by lamination or molding so as to form a heat dissipation covering layer 32 covering a plurality of conductive pillars 33 and the electronic element 21. It should be understood that in subsequent processes, there is no need to fabricate the second conductive pillars of the aforementioned embodiments, and the processes shown in FIG. 2E to FIG. 2G can be directly performed, so that the circuit structure 26 is formed on the heat dissipation covering layer 32 and electrically connected to the plurality of conductive pillars 33.

Therefore, in the manufacturing method of the present disclosure, the heat dissipation covering layer 32 with excellent thermal conductivity covers the electronic element 21 and is in contact with the metal layer 28 to quickly dissipate heat around the electronic element 21 so as to effectively avoid the problem of failure of the electronic element 21 due to overheating during operation.

The present disclosure further provides an electronic package 2, 3, which comprises: a carrier structure 20, at least one electronic element 21, a heat dissipation covering layer 22, 32 and a metal layer 28.

The electronic element 21 is bonded on and electrically connected to the carrier structure 20.

The heat dissipation covering layer 22, 32 is formed on the carrier structure 20 to cover the electronic element 21.

The metal layer 28 is formed on a side surface S of the carrier structure 20 and in contact with the heat dissipation covering layer 22, 32.

In one embodiment, the heat dissipation covering layer 22 is made of metal material.

In one embodiment, a material forming the heat dissipation covering layer 32 is a thermally conductive insulating material.

In one embodiment, the electronic package 2, 3 further comprises at least one conductive pillar 23, 33 disposed on the carrier structure 20 and electrically connected to the carrier structure 20. For example, the heat dissipation covering layer 22, 32 is in contact with the conductive pillar 23, 33. Alternatively, the heat dissipation covering layer 22 has an opening 220, so that the conductive pillar 23 passes through the opening 220 without touching the opening 220. Furthermore, the electronic package 3 further comprises a circuit structure 26 disposed on the heat dissipation covering layer 32 and electrically connected to the conductive pillar 33.

In one embodiment, the electronic package 2 further comprises a packaging layer 25 formed on the carrier structure 20, so that the packaging layer 25 covers the electronic element 21 and the heat dissipation covering layer 22. For example, the electronic package 2 also comprises at least one conductive pillar 23, 23a disposed on the carrier structure 20 and electrically connected to the carrier structure 20, and the conductive pillar 23, 23a is embedded in the packaging layer 25. Furthermore, the electronic package 2 may comprise a circuit structure 26 disposed on the packaging layer 25 and electrically connected to the conductive pillar 23, 23a.

In view of the above, in the electronic package and the manufacturing method thereof of the present disclosure, the heat dissipation covering layer with excellent thermal conductivity is in contact with the metal layer to quickly dissipate heat around the electronic element. Therefore, the electronic element is covered by the heat dissipation covering layer in the present disclosure, which can effectively avoid the problem of failure of the electronic element due to overheating during operation, thereby avoiding the problem of scrapping terminal electronic products.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic element bonded on and electrically connected to the carrier structure;
a heat dissipation covering layer formed on the carrier structure and covering the electronic element; and
a metal layer formed on a side surface of the carrier structure and in contact with the heat dissipation covering layer.

2. The electronic package of claim 1, wherein a material forming the heat dissipation covering layer is a metal material.

3. The electronic package of claim 1, wherein a material forming the heat dissipation covering layer is a thermally conductive insulating material.

4. The electronic package of claim 1, further comprising a plurality of conductive pillars disposed on and electrically connected to the carrier structure.

5. The electronic package of claim 4, wherein the heat dissipation covering layer is in contact with the plurality of conductive pillars.

6. The electronic package of claim 4, wherein the heat dissipation covering layer has a plurality of openings, and the plurality of conductive pillars pass through the plurality of openings without touching the plurality of openings.

7. The electronic package of claim 4, further comprising a circuit structure disposed on the heat dissipation covering layer and electrically connected to the plurality of conductive pillars.

8. The electronic package of claim 1, further comprising a packaging layer formed on the carrier structure and covering the electronic element and the heat dissipation covering layer.

9. The electronic package of claim 8, further comprising a plurality of conductive pillars disposed on and electrically connected to the carrier structure, wherein the plurality of conductive pillars are embedded in the packaging layer.

10. The electronic package of claim 9, further comprising a circuit structure disposed on the packaging layer and electrically connected to the plurality of conductive pillars.

11. A method of manufacturing an electronic package, comprising:
providing a carrier structure disposed with an electronic element, wherein the electronic element is electrically connected to the carrier structure;
forming a heat dissipation covering layer on the carrier structure, wherein the electronic element is covered by the heat dissipation covering layer; and
forming a metal layer on a side surface of the carrier structure, wherein the metal layer is in contact with the heat dissipation covering layer.

12. The method of claim 11, wherein a material forming the heat dissipation covering layer is a metal material.

13. The method of claim 11, wherein a material forming the heat dissipation covering layer is a thermally conductive insulating material.

14. The method of claim 11, further comprising forming a plurality of conductive pillars on the carrier structure, wherein the plurality of conductive pillars are electrically connected to the carrier structure.

15. The method of claim 14, wherein the heat dissipation covering layer is in contact with the plurality of conductive pillars.

16. The method of claim 14, wherein the heat dissipation covering layer has a plurality of openings, and the plurality of conductive pillars pass through the plurality of openings without touching the plurality of openings.

17. The method of claim 14, further comprising forming a circuit structure on the heat dissipation covering layer, wherein the circuit structure is electrically connected to the plurality of conductive pillars.

18. The method of claim 11, further comprising forming a packaging layer on the carrier structure to cover the electronic element and the heat dissipation covering layer.

19. The method of claim 18, further comprising forming a plurality of conductive pillars on the carrier structure, wherein the plurality of conductive pillars are electrically connected to the carrier structure and embedded in the packaging layer.

20. The method of claim 19, further comprising forming a circuit structure on the packaging layer, wherein the circuit structure is electrically connected to the plurality of conductive pillars.
